(19) United States
(12) Patent Application Publication
(10) Pub. No.: US 2006/0019128 A1
(43) Pub. Date: Jan. 26, 2006

(54) Magnetic recording medium and method for evaluating magnetic recording medium

(75) Inventors: Hiroyuki Tanaka, Tokyo (JP); Takashi Handa, Tokyo (JP); Tomoyuki Kotaki, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: TDK Corporation, Tokyo (JP)

(21) Appl. No.: 10/895,846

(22) Filed: Jul. 22, 2004

(51) Int. Cl. G11B 5/716; G01R 33/00

(52) U.S. Cl. 428/840.3; 324/200

(57) ABSTRACT

A magnetic recording medium which has a thin film magnetic layer considerably excellent in surface smoothness and is excellent in electromagnetic conversion property is provided. A method for evaluating the surface smoothness of a magnetic recording medium is also provided. A magnetic recording medium comprising: a non-magnetic support; a non-magnetic layer which is on one surface of the non-magnetic support and comprises at least carbon black, a non-magnetic-powder other than the carbon black and a binder resin; and a magnetic layer which is on the non-magnetic layer and comprises at least a ferromagnetic powder and a binder resin, wherein when the shape of irregularities of the surface of the magnetic layer is subjected to Fourier transformation to obtain the power spectrum density (PSD) in the longitudinal direction of the magnetic recording medium, the power spectrum density L₂ at a wavelength 2λ in the longitudinal direction, wherein λ (μm) represents the shortest recording wavelength of a recording and reproducing device for the magnetic recording medium, is 6.0×10⁻⁶ nm²mm or less. A magnetic recording medium, wherein when the power spectrum density (PSD) in the width direction of the magnetic recording medium is obtained, the power spectrum density W₂ at a wavelength 2λ in the width direction, wherein λ (μm) represents the shortest recording wavelength of a recording and reproducing device for the magnetic recording medium, is 3.5×10⁻⁶ nm²mm or less.

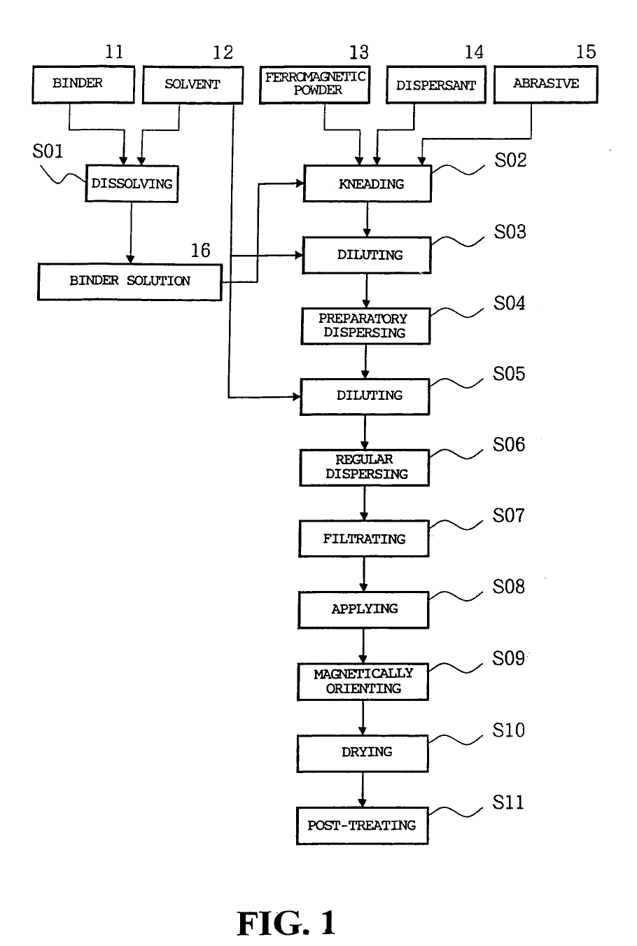

### BACKGROUND OF THE INVENTION

1. Field of the Invention

The present invention relates to a magnetic recording medium, in particular, a magnetic recording medium having a thin magnetic layer excellent in surface smoothness and electromagnetic conversion property. The present invention also relates to a method for evaluating the surface smoothness of a magnetic recording medium.

2. Disclosure of the Related Art

Conventionally, magnetic recording media have a magnetic layer on one surface of a non-magnetic support, and have a back coat layer on the other surface of the non-magnetic support in order to improve the running durability thereof and others.

In recent years, the recording density of magnetic recording media has been desired to be made high in order to cope with an increase in the quantity of recording data. In order to make the recording density of the media higher, the recording wavelength thereof has been made shorter and the magnetic layer has been made thinner.

In the case that the magnetic layer is made thin, the surface roughness of the support is reflected on the surface of the magnetic layer so that the smoothness of the magnetic layer surface is damaged. Consequently, the electromagnetic conversion property of the magnetic layer deteriorates. For this reason, for example, a non-magnetic layer is formed as an undercoat layer on the surface of the support, and then the magnetic layer is formed on this non-magnetic layer.

As the recording wavelength is made shorter, the magnetic layer surface is required to be made smoother from the viewpoint of spacing loss.

Japanese Laid-Open Patent Publication No. 2001-297422 discloses a magnetic recording medium comprising a magnetic layer formed on a non-magnetic support, wherein about each wavelength x (μm) within the range of 5 μm to 100 μm (both inclusive) in the power spectrum obtained by subjecting the surface of the magnetic layer to Fourier transformation, at the time of defining the product of the number of waves and the height of the waves as the intensity y and approximating the relationship between the wavelength x (am) and the intensity y by the following equation:
y=ax^{b} (wherein a and b are each a coefficient),

the coefficients a and b satisfy the following: 0.0001≦a≦0.005 and 0.6≦b. This publication also discloses a magnetic recording medium wherein the long axis length of magnetic powder contained in a magnetic layer is 0.25 μm or less; and the thickness of a coating film which is formed on a non-magnetic support and is made of a magnetic layer, plural magnetic layers, or the magnetic layer and an undercoat layer or intermediate layer is 0.5 μm or more.

### SUMMARY OF THE INVENTION

However, in order to make the recording density of magnetic recording media higher, it is desired to make the recording wavelength thereof even shorter and make the magnetic layer thereof even thinner. For this purpose, it is indispensable that the surface of the magnetic layer made even thinner is made even smoother, that is, irregularities of the magnetic layer surface is made even more minute in light of the recording wavelength made even shorter.

An object of the present invention is to provide a magnetic recording medium which has a thin magnetic layer excellent in surface smoothness and is excellent in electromagnetic conversion property. Another object of the present invention is to provide a method for evaluating the surface smoothness of a magnetic recording medium.

The present invention includes the following aspects.

(1) A magnetic recording medium comprising:

a non-magnetic support;

a non-magnetic layer which is formed on one surface of the non-magnetic support and comprises at least carbon black, a non-magnetic powder other than the carbon black and a binder resin; and

a magnetic layer which is formed on the non-magnetic layer and comprises at least a ferromagnetic powder and a binder resin, wherein

when the shape of irregularities of the surface of the magnetic layer is subjected to Fourier transformation to obtain the power spectrum density (PSD) in the longitudinal direction of the magnetic recording medium, the power spectrum density L₂ at a wavelength 2λ in the longitudinal direction, wherein λ (μm) represents the shortest recording wavelength of a recording and reproducing device for the magnetic recording medium, is 6.0×10⁻⁶ nm²mm or less.

(2) The magnetic recording medium according to the above (1), wherein the average long axis length of the ferromagnetic powder is 60 nm or less.

(3) The magnetic recording medium according to the above (1), wherein the magnetic layer has a thickness of 100 nm or less.

(4) The magnetic recording medium according to the above (1), wherein a recorded signal is reproduced by use of a magneto-resistive effect type head (MR head).

(5) A magnetic recording medium comprising:

a non-magnetic support;

a non-magnetic layer which is formed on one surface of the non-magnetic support and comprises at least carbon black, a non-magnetic powder other than the carbon black and a binder resin; and

a magnetic layer which is formed on the non-magnetic layer and comprises at least a ferromagnetic powder and a binder resin, wherein

when the shape of irregularities of the surface of the magnetic layer is subjected to Fourier transformation to obtain the power spectrum density (PSD) in the width direction of the magnetic recording medium, the power spectrum density W₂ at a wavelength 2λ in the width direction, wherein λ (μm) represents the shortest recording wavelength of a recording and reproducing device for the magnetic recording medium, is 3.5×10⁻⁶ nm²mm or less.

(6) The magnetic recording medium according to the above (5), wherein the average long axis length of the ferromagnetic powder is 60 nm or less.

(7) The magnetic recording medium according to the above (5), wherein the magnetic layer has a thickness of 100 nm or less.

(8) The magnetic recording medium according to the above (5), wherein a recorded signal is reproduced by use of a magneto-resistive effect type head (MR head).

(9) A method for evaluating a magnetic recording medium comprising at least a non-magnetic support and a magnetic layer on one surface of the support, the method comprising the steps of:

subjecting the shape of irregularities of the surface of the magnetic layer to Fourier transformation, thereby obtaining the power spectrum density (PSD) in the longitudinal direction of the magnetic recording medium; and

judging the quality of the surface of the magnetic recording medium on the basis of the power spectrum density at any wavelength selected from the wavelength range of 2λ to 10λ in the longitudinal direction, wherein λ (μm) represents the shortest recording wavelength of a recording and reproducing device for the magnetic recording medium.

(10) The method for evaluating the magnetic recording medium according to the above (9), wherein the magnetic recording medium in which the power spectrum density L₂ at the wavelength 2λ in the longitudinal direction is 6.0×10⁻⁶ nm²mm or less is judged as a good medium.

(11) A method for evaluating a magnetic recording medium comprising at least a non-magnetic support and a magnetic layer on one surface of the support, the method comprising the steps of:

subjecting the shape of irregularities of the surface of the magnetic layer to Fourier transformation, thereby obtaining the power spectrum density (PSD) in the width direction of the magnetic recording medium; and

judging the quality of the surface of the magnetic recording medium on the basis of the power spectrum density at any wavelength selected from the wavelength range of 2λ to 10λ in the width direction, wherein λ (μm) represents the shortest recording wavelength of a recording and reproducing device for the magnetic recording medium.

(12) The method for evaluating the magnetic recording medium according to the above (11), wherein the magnetic recording medium in which the intensity W₂ of the power spectrum density at the wavelength 2λ in the width direction is 3.5×10⁻⁶ nm²mm or less is judged as a good medium.

According to the present invention, provided is a magnetic recording medium which has a thin magnetic layer considerably excellent in surface smoothness and is excellent in electromagnetic conversion property. The magnetic recording medium of the present invention is particularly suitable as a recording medium for computers in which recorded signals are reproduced by use of a magneto-resistive effect type head (MR head).

According to the present invention, provided is also a method for evaluating the surface smoothness of a magnetic recording medium which has a magnetic layer made thin and is suitable for recording and reproducing signals by use of a recording wavelength made short.

### BRIEF DESCRIPTION OF THE DRAWING

Figure is a flowchart showing a preferred production example of a coating material for forming a magnetic layer.

### DETAILED DESCRIPTION OF THE INVENTION

The magnetic recording medium of the present invention will be described in detail hereinafter.

In an example of the magnetic recording medium of the present invention, a lower non-magnetic layer is formed on one surface of a non-magnetic support, an upper magnetic layer having a thickness of 100 nm (0.10 μm) or less is formed on the lower non-magnetic layer, and further a back coat layer is formed on the other surface of the non-magnetic support. In the present invention, a lubricant coating film and various coating films for protecting the magnetic layer may be formed on the surface of the magnetic layer if necessary. An undercoat layer (adhesive layer) may be formed on the surface of the non-magnetic support on which the magnetic layer is to be formed, in order to improve adhesion of the coating film and the non-magnetic support, and other effects.

[Lower Non-Magnetic Layer]

The lower non-magnetic layer comprises carbon black, a non-magnetic inorganic powder other than the carbon black, and a binder resin. The non-magnetic inorganic powder other than the carbon black comprises acicular iron oxide powder.

The carbon black comprised in the non-magnetic layer may be furnace black for rubber, thermal black for rubber, black for color, acetylene black or the like. It is preferred that the specific area thereof is from 5 to 600 m²/g, the DBP oil absorption thereof is from 30 to 400 mL/100 g, and the particle size thereof is from 10 to 100 nm. For the carbon black which can be used, specifically, “carbon black guide book” edited by the Carbon Black Association of Japan can be referred to.

The non-magnetic inorganic powder other than the carbon black, which can be used in the non-magnetic layer, maybe selected from various non-magnetic inorganic powders. Examples of the inorganic powders include acicular non-magnetic iron oxide (α-Fe₂O₃), CaCO₃, titanium oxide, barium sulfate, and α-Al₂O₃.

The blend ratio by weight of the carbon black to the inorganic powder other than the carbon black (the carbon black/the inorganic powder) is preferably from 100/0 to 5/95. If the proportion of the carbon black is less than 5 parts by weight, a problem about the surface electric resistance is caused.

Besides the above-mentioned material, the following is used as a binder in the lower non-magnetic layer: a combination that is appropriately selected from thermoplastic resins, thermosetting or thermoreactive resins, radial ray- (electron ray- or ultraviolet ray-) curable resins and other resins in accordance with the property of the medium or conditions for the production process thereof.

Of these combinations, preferable is a combination of a vinyl chloride type copolymer, as described below, with a polyurethane resin.

The vinyl chloride type copolymer is preferably one having a vinyl chloride content of 60 to 95% by weight, and is more preferably one having a vinyl chloride content of 60 to 90% by weight. The average polymerization degree thereof is preferably from about 100 to 500. Particularly preferable is a copolymer made from vinyl chloride and a monomer having an epoxy (glycidyl) group.

The polyurethane resin, which is used together with the vinyl chloride type resin, is a generic name given to resins obtained by reaction of hydroxyl-containing resins, such as polyester polyol and/or polyether polyol, with polyisocyanate-containing compounds. The number-average molecular weight thereof is from about 5,000 to 200,000, and the Q value (i.e., the weight-average molecular weight/the number-average molecular weight) thereof is from about 1.5 to 4.

The non-magnetic layer may comprise various known resins in an amount of 20% or less by weight of the whole of the binder(s) besides the vinyl chloride type copolymer and the polyurethane resin.

As a crosslinking agent for curing these binder resins, various polyisocyanates, in particular, diisocyanate can be used. It is particularly preferable to use one or more selected from tolylene diisocyanate, hexamethylene diisocyanate and methylene diisocyanate. The content of the crosslinking agent is preferably from 10 to 30 parts by weight for 100 parts by weight of the binder resin(s). In order to cure such a thermosetting resin, it is generally advisable to heat the resin at 50 to 70° C. in a heating oven for 12 to 48 hours.

It is allowable to use the above-mentioned binder resin(s) the electron beam sensitivity of which is modified by the introduction of (meth)acrylic double bonds into the resin in a known manner.

When the electron beam curing binder resin(s) is/are used, a known polyfunctional acrylate may be used in an amount of 1 to 50 parts by weight, preferably 5 to 40 parts by weight for 100 parts by weight of the binder resin(s) in order to improve the cross-linkage ratio of the resin(s).

The content of the binder resin(s) used in the lower non-magnetic layer is preferably from 10 to 100 parts by weight, more preferably from 12 to 30 parts by weight for 100 parts by weight of the total of the carbon black and the inorganic powder other than the carbon black in the lower non-magnetic layer. If the content of the binder(s) is too small, the ratio of the binder resin(s) in the lower non-magnetic layer lowers so that a sufficient coating film strength cannot be obtained. If the content of the binder is too large, the medium, when being made into a tape, is easily warped along the width direction of the tape. Consequently, the state of contact between the tape and a head tends to get bad.

It is preferred that the lower non-magnetic layer comprises a lubricant if necessary. The lubricant may be saturated or unsaturated, and may be a known lubricant, examples of which include fatty acids such as stearic acid and myristic acid; fatty acid esters such as butyl stearate and butyl palmitate; and sugars. These may be used alone or in a mixture of two or more thereof. It is preferred to use a mixture of two or more fatty acids having different melting points, or a mixture of two or more fatty acid esters having different melting points. This is because it is necessary to supply lubricants adapted to all temperature environments in which the magnetic recording medium is used onto the surface of the medium without interruption.

The lubricant content in the lower non-magnetic layer may be appropriately adjusted in accordance with purpose, and is preferably from 1 to 20% by weight of the total weight of the carbon black and the non-magnetic inorganic powder other than the carbon black.

A coating material for forming the lower non-magnetic layer is prepared by adding an organic solvent to the above-mentioned components and subjecting the resultant to mixing, stirring, kneading, dispersing and other treatments in a known manner. The used solvent is not limited to any especial kind, and may be appropriately selected from various solvents such as ketone solvents (such as methyl ethyl ketone, methyl isobutyl ketone, and cyclohexane) and aromatic solvents (such as toluene). These may be used alone or in combination of two or more thereof. The amount of the added organic solvent is set into the range of about 100 to 900 parts by weight for 100 parts by weight of the total of the carbon black, the inorganic powder(s) other than the carbon black, and the binder resin(s).

The thickness of the lower non-magnetic layer is usually from 0.3 to 2.5 μm, preferably from 0.3 to 2.3 μm. If the non-magnetic layer is too thin, the layer is easily affected by the surface roughness of the non-magnetic support so that the surface smoothness of the non-magnetic layer deteriorates and, also, the surface smoothness of the magnetic layer deteriorates easily. Consequently, the electromagnetic property thereof tends to deteriorate. The light transmittance also becomes high. Therefore, a problem is caused when the end of the medium is detected by a change in the light transmittance. On the other hand, if the non-magnetic layer is made thicker than some value, the performance thereof is not improved.

[Upper magnetic layer]

The upper magnetic layer comprises at least a ferromagnetic powder and a binder resin.

The average long axis length of the ferromagnetic powder is preferably 60 nm or less, that is, 0.06 μm or less. The use of the ferromagnetic powder having the short long axis length causes the filling rate in the coating film to be raised so that the electromagnetic conversion property is improved. The average long axis length of a preferred example of the ferromagnetic powder is from 0.03 to 0.06 μm. If the average long axis length of the ferromagnetic powder is more than 0.06 μm, the electromagnetic conversion property tends to deteriorate. On the other hand, if the average long axis length is less than 0.03 μm, the magnetic anisotropy weakens so that the powder is not easily oriented. Consequently, the output of the magnetic layer is apt to lower.

In the present invention, the ferromagnetic powder is preferably a metal magnetic powder or a planar hexagonal fine powder. The metal magnetic powder preferably has a coercive force Hc of 118.5 to 237 kA/m (1500 to 3000 Oe), a saturation magnetization σs of 120 to 160 Am²/kg (emu/g), an average long axis length of 0.03 to 0.1 μm, an average short axis length of 10 to 20 nm, and an aspect ratio of 1.2 to 20. The Hc of the medium produced by use of the metal magnetic powder is preferably from 118.5 to 237 kA/m (1500 to 3000 Oe). The planar hexagonal fine powder preferably has a coercive force Hc of 79 to 237 kA/m (1000 to 3000 Oe), a saturation magnetization σs of 50 to 70 Am²/kg (emu/g), an average planar particle size of 30 to 80 nm, and a plate ratio of 3 to 7. The Hc of the medium produced by use of the planar hexagonal fine powder is preferably from 94.8 to 173.8 kA/m (1200 to 2200 Oe).

The average long axis length of the ferromagnetic powder can be obtained by separating and collecting the magnetic powder from a tape piece and then measuring the long axis length of each powder from a photograph taken with a transmission electron microscope (TEM). One example of the steps for obtaining the length is described in the following: (1) from the tape piece, the back coat layer is wiped off with a solvent, so as to be removed; (2) the tape piece sample wherein the lower non-magnetic layer and the upper magnetic layer remain on the non-magnetic support is immersed into a 5% aqueous NaOH solution, and then solution is heated and stirred; (3) the coating film which is caused to fall out from the non-magnetic support is washed with water, and then dried; (4) the dried coating film is subjected to ultrasonic treatment in methyl ethyl ketone (MEK), and a magnetic stirrer is used to adsorb and collect the magnetic powder; (5) the magnetic powder is separated from the residue and then dried; (6) the magnetic powders obtained in the above (4) and (5) are combined and put into an exclusive mesh to prepare a sample for transmission electron microscopy, and then a photograph of the sample is taken with a transmission electron microscope; and (7) the lengths of long axes of particles of the photographed magnetic powder are measured, and the resultant values are averaged (the number of the measured particles: n=100).

It is advisable that the magnetic layer comprises the ferromagnetic powder in an amount of about 70 to 90% by weight of the layer. If the content of the ferromagnetic powder is too large, the content of the binder decreases so that the surface smoothness deteriorates easily by calendering. On the other hand, if the content of the ferromagnetic powder is too small, a high reproducing output cannot be obtained.

The binder agent for the magnetic layer is not limited to any especial kind, and the following may be used: a combination that is appropriately selected from thermoplastic resins, thermosetting or thermoreactive resins, radial ray- (electron ray- or ultraviolet ray-) curable resins and other resins in accordance with the property of the medium or conditions for the production process thereof. The binder resin which can be used may be appropriately selected from the same binders as described about the lower non-magnetic layer.

The content of the binder resin used in the magnetic layer is preferably from 5 to 40 parts by weight, more preferably from 10 to 30 parts by weight for 100 parts by weight of the ferromagnetic powder. If the content of the binder is too small, the strength of the magnetic layer lowers so that the running durability of the medium deteriorates easily. On the other hand, if the content of the binder is too large, the content of the ferromagnetic powder lowers so that the electromagnetic conversion property tends to deteriorate.

The magnetic layer further contains an abrasive having a Mohs hardness of 6 or more, such as α-alumina (Mohs hardness: 9), for the purposes of increasing the mechanical strength of the magnetic layer and preventing clogging of the magnetic head. Such an abrasive usually has an indeterminate form, causes the magnetic head to be prevented from clogging, and causes the strength of the coating film to be improved.

The average particle size of the abrasive is, for example, from 0.01 to 0.2 μm, preferably from 0.05 to 0.2 μm. If the average particle size of the abrasive is too large, then the projections from the surface of the magnetic layer become significant, causing a decrease in the electromagnetic conversion characteristics, an increase in the drop-outs, and an increase in the head wear. Conversely, if the average particle size of the abrasive is too small, then the projections from the surface of the magnetic layer become relatively small, leading to insufficient prevention of clogged heads.

The average particle size is usually measured with a transmission electron microscope. The content of the abrasive may be from 3 to 25 parts by weight, preferably from 5 to 20 parts by weight for 100 parts by weight of the ferromagnetic powder.

If necessary, various additives may be added to the magnetic layer, examples of the additives including dispersants such as a surfactant, and lubricants such as higher fatty acid, fatty acid ester, and silicone oil.

A coating material for forming the magnetic layer is prepared by adding an organic solvent to the above-mentioned components. The organic solvent to be used is not limited to any especial kind, and may be the same as used in the lower non-magnetic layer.

The thickness of the magnetic layer is preferably 100 nm or less, that is, 0.1 μm or less, more preferably from 0.01 to 0.1 μm. If the magnetic layer is too thick, the self demagnetization loss or thickness loss thereof increases.

The smoothness of the magnetic layer surface is important for the present invention. It is indispensable that irregularities of the magnetic layer surface are made very minute in light of the recording wavelength made short.

About the magnetic recording medium of the present invention, when the shape of irregularities of the surface of the magnetic layer is subjected to Fourier transformation to obtain the power spectrum density (PSD) in the longitudinal direction of the magnetic recording medium, the power spectrum density L₂ at a wavelength 2λ in the longitudinal direction, wherein λ (μm) represents the shortest recording wavelength of a recording and reproducing device for the magnetic recording medium, is 6.0×10⁻⁶ nm²mm or less.

About the magnetic recording medium of the present invention, when the shape of irregularities of the surface of the magnetic layer is subjected to Fourier transformation to obtain the power spectrum density (PSD) in the width direction of the magnetic recording medium, the power spectrum density W₂ at a wavelength 2λ in the width direction, wherein λ (μm) represents the shortest recording wavelength of a recording and reproducing device for the magnetic recording medium, is 3.5×10⁻⁶ nm²mm or less.

In this context, the shape of irregularities means the heights and positions of the irregularities. In the present invention, data of the heights and positions of the irregularities is subjected to Fourier transformation.

The shape of the irregularities of the magnetic layer surface can be obtained from image data projected, via light interference, onto a CCD camera. In other words, the color tone of each pixel corresponds to the height of each of the irregularities, and the position of each pixel corresponds to the position of each of the irregularities.

The longitudinal direction of the magnetic recording medium is the direction in which a used magnetic head travels, that is, the direction in which recording signals are recorded, or the direction along tracks of the medium. The width direction of the magnetic recording medium is the direction perpendicular to the longitudinal direction, that is, the direction along which the tracks are arranged.

The power spectrum densities (PSDs) in the longitudinal direction and the width direction of the magnetic layer surface can be obtained by dividing a measuring area of 93.9 μm (in the longitudinal direction)×123.5 μm (in the width direction) of the magnetic layer surface into 480 pixels (in the longitudinal direction)×736 pixels (in the width direction), so as to make the area of each of the pixels into 0.20 μm (in the longitudinal direction)×0.17 μm (in the width direction); measuring the shape of minute irregularities of the measuring area in the magnetic layer surface; and then subjecting the resultant heights of the irregularities to Fourier transformation.

When the shortest recording wavelength of the recording and reproducing device for the magnetic recording medium is represented by λ μm, about the magnetic recording medium of the present invention, the power spectrum density L₂ at the wavelength 2λ in the longitudinal direction is 6.0×10⁻⁶ nm²mm or less, preferably from 1.0×10⁻⁶ to 5.0×10⁻⁶ nm²mm (both inclusive). When the L₂ is 6.0×10⁻⁶ nm²mm or less, spacing loss based on undulation near the recording wavelength is decreased so that signal defects are suppressed. As the shortest recording wavelength λ of the recording and reproducing device, a wavelength λ of 0.01 to 0.3 μm is preferably used.

When the shortest recording wavelength of the recording and reproducing device for the magnetic recording medium is represented by λ μm as described above, about the magnetic recording medium of the present invention, the power spectrum density W₂ at the wavelength 2λ in the width direction is 3.5×10⁻⁶ nm²mm or less, preferably from 3.0×10⁻⁷ to 2.5×10⁻⁶ nm²mm (both inclusive). When the W₂ is 3.5×10⁻⁶ nm²mm or less, spacing loss based on undulation near the recording wavelength is decreased so that signal defects are suppressed. As the shortest recording wavelength λ of the recording and reproducing device, a wavelength λ of 0.01 to 0.3 μm is preferably used.

When the shortest recording wavelength of the recording and reproducing device for the magnetic recording medium is represented by λ μm as described above, about the magnetic recording medium of the present invention, it is more preferable that the power spectrum density L₂ at the wavelength 2λ in the longitudinal direction is 6.0×10⁻⁶ nm²mm or less and further the power spectrum density W₂ at the wavelength 2λ in the width direction is 3.5×10⁻⁶ nm²mm or less. It is most preferable that the power spectrum density L₂ in the longitudinal direction is from 1.0×10⁻⁶ to 5.0×10⁻⁶ nm²mm (both inclusive) and further the power spectrum density W₂ in the width direction is from 3.0×10⁻⁷ to 2.5×10⁻⁶ nm²mm (both inclusive).

In order to form the magnetic layer having a surface consistent with the present invention, it is necessary to make dispersed particles in a coating material for forming the magnetic layer fine and make the dispersion state thereof good. With reference to the attached figure, the following describes a preferred example of the process for producing the coating material for the magnetic layer.

When the coating material is produced, a binder 11, a solvent 12, a ferromagnetic powder 13, a dispersant 14, an abrasive 15 and others are successively mixed and then the mixture is subjected to kneading, diluting, dispersing and other steps to prepare the coating material.

Dispersing conditions in a regular dispersing step (S06) performed after a preparatory dispersing step (S04), among the above-mentioned producing steps for the coating material, are appropriately decided, thereby making it possible to yield a surface smoothness having a reduced power spectrum density of the shape of the irregularities at the wavelength 2λ μm, which is a wavelength twice the shortest recording wavelength λ μm.

Dispersing media which can be preferably used in this regular dispersing step (S06) are specifically media having an average particle size of 0.8 mm or less.

In the preparatory dispersing step (S04), the above-mentioned mixed solution is dispersed in a high concentration state of about 25 to 40% by weight (solid content). Subsequently, in the regular dispersing step (S06), the coating material diluted into a concentration of about 5 to 20% by weight is dispersed by use of zirconia beads having an average particle size of 0.7 mm or less as the dispersing media in a disperser. The dispersing peripheral velocity of the disperser is set into the range of about 8 to 15 m/s. In this way, a magnetic layer coating material which is in a good dispersion state can be obtained.

If the concentration of the coating material in the regular dispersing step (S06) is too high, the movement of the dispersing media having an average particle size of 0.7 mm or less is blocked since the average particle size is small so that the weight is also small. Thus, the media cannot exhibit a sufficient dispersing capability, so that the ferromagnetic powder is not sufficiently loosened into primary particle sizes. Moreover, the pressure of the coating material is easily raised. Consequently, inconveniences for the dispersing apparatus, such that the flow rate of the coating material cannot be increased, are caused.

The dispersing peripheral velocity of the disperser is preferably about 8 to 15 m/s. If the dispersing peripheral velocity is too large, a large amount of heat is generated from the dispersing apparatus or the coating material and further the non-magnetic powder or the ferromagnetic powder is easily broken. On the other hand, if the dispersing peripheral velocity is too small, the pigment tends not to be sufficiently loosened into primary particle sizes.

With reference to the flowchart shown in the attached figure, an example of the process for producing a coating material are specifically described hereinafter.

First, a binder 11 made of a resin material or the like is dissolved into a solvent 12 to prepare a binder solution 16 (S01). Next, the resultant binder solution 16, a ferromagnetic powder 13, a dispersant 14, and an abrasive 15 are kneaded (S02). Furthermore, a solvent 12 is added thereto, and the resultant is dissolved or diluted (S03), thereby yielding a mixed solution comprising at least the binder 11, the ferromagnetic powder 13, and the solvent 12. As the method for preparing the mixed solution, a known method may be appropriately used. For example, a continuous kneader, a pressing kneader or the like is used to knead the materials, and then a dissolver or the like is used to perform stirring, dissolving or diluting operation while a solvent is added thereto. In this way, a mixed solution can be prepared. The order of the mixture of the materials is not limited to the example illustrated.

The resultant mixed solution is supplied into a vessel of a disperser, in which a given amount of dispersing media is beforehand charged, and then a stirring unit which is set inside the vessel and has many stirring disks, a wing-form stirring body, stirring pins or the like is rotated at a given peripheral velocity to conduct preparatory dispersing treatment (S04). In this preparatory dispersing treatment (S04), the coating material having a high concentration is dispersed. Usually, the mixed solution obtained by kneading the binder, the ferromagnetic powder and the solvent contains large aggregated lumps. In order to loosen the lumps, the preparatory dispersing treatment is performed so as to increase the number of collisions between the aggregated lumps and the dispersing media. About the present invention, it is advisable that regular dispersion is performed after this preparatory dispersing treatment once makes the coating material into a homogeneous dispersion state and then the coating material is diluted to reduce its concentration so that light dispersing media which have a small particle size and are to be used in the regular dispersing treatment can move around sufficiently in the coating material to exhibit a sufficient dispersing capability.

The preparatory dispersing treatment may be any treatment capable of dispersing the ferromagnetic powder into the mixed solution having a high concentration (for example, a solid concentration of about 25 to 40% by weight) to an appropriate extent. Conditions for the treatment may be known dispersing conditions, and are not particularly limited.

Next, a solvent is added to the mixed solution wherein the ferromagnetic powder 13 is subjected to the preparatory dispersion as described above, and then the solution is diluted to have a desired concentration of the coating material as described above (S05). Thereafter, the above-mentioned regular dispersing treatment is conducted (S06).

In this way, a magnetic layer coating material which contains fine dispersed particles and is in a good dispersion state is obtained, and the coating material can be used suitably for the present invention.

[Back Coat Layer]

The back boat layer is formed to improve the running stability of the magnetic recording medium, prevent the electrification of the magnetic layer and attain others. The structure and the composition thereof are not particularly limited. The back coat layer may comprise, for example, carbon black, a non-magnetic inorganic powder other than the carbon black, and a binder resin.

The back coat layer preferably comprises the carbon black in an amount of 30 to 80% by weight of the back coat layer.

The non-magnetic inorganic powder other than the carbon black, which contained in the back coat layer, may be selected from various non-magnetic inorganic powders in order to control the mechanical strength of this layer. Examples of the inorganic powder include α-Fe₂O₃, CaCO₃, titanium oxide, barium sulfate, and α-Al₂O₃ powders.

A coating material for forming the back coat layer is prepared by adding an organic solvent to the above-mentioned components and subjecting the resultant to mixing, stirring, kneading, dispersing and other treatments in a known manner. The used solvent is not limited to any especial kind, and may be the same as used in the lower non-magnetic layer.

The thickness of the back coat layer is 1.0 μm or less, preferably from 0.1 to 1.0 μm, more preferably from 0.2 to 0.8 μm (after the layer is calendered).

[Non-Magnetic Support]

The material used for the non-magnetic support is not particularly limited, and may be selected from various flexible materials and various rigid materials in accordance with purpose. The material is made into a give form, such as a medium form, and a given size in accordance with various standard specifications. Examples of the flexible materials include polyesters such as polyethylene terephthalate and polyethylene naphthalate; polyolefins such as polypropylene; polyamides; polyimides; and polycarbonates.

The thickness of the non-magnetic support is preferably from 3.0 to 15.0 μm. The form of the non-magnetic support is not particularly limited, and may be any one selected from tape, sheet, card, disc and other forms. In accordance with the form or circumferences, various materials may be selected and used.

[Production of Magnetic Recording Medium]

In the present invention, the non-magnetic layer and the magnetic layer may be formed in a wet-on-dry coating or a wet-on-wet coating manner, so as to produce a magnetic recording medium. In the case of the wet-on-dry coating manner, the coating material for the non-magnetic layer is first applied onto one surface of the non-magnetic support, dried and calendered. Thereafter, the coating material is cured to form the lower non-magnetic layer. Next, the coating material for the magnetic layer is applied onto the cured lower non-magnetic layer, oriented, and dried to form the upper magnetic layer. In the case of the wet-on-wet coating manner, the magnetic layer is formed while the lower non-magnetic layer is in a wet state.

According to the wet-on-dry coating manner, there is not caused disturbance in the interface between the non-magnetic layer and the magnetic layer, as is seen in the wet-on-wet coating manner, wherein the magnetic layer is applied while the non-magnetic layer is in a wet state. For this reason, the obtained magnetic layer is excellent in electromagnetic conversion property. Therefore, the wet-on-dry coating manner is preferable.

The method used for applying the above-mentioned coating materials may be any one selected from known various coating methods such as gravure coating, reverse roll coating, die nozzle coating, and bar coating.

The present invention also relates to a method for evaluating a magnetic recording-medium comprising at least a non-magnetic support and a magnetic layer formed on one surface of the support.

That is, the present invention relates to a method comprising the steps of:

subjecting the shape of irregularities of the surface of the magnetic layer to Fourier transformation, thereby obtaining the power spectrum density (PSD) in the longitudinal direction of the magnetic recording medium; and

judging the quality of the surface of the magnetic recording medium on the basis of the power spectrum density at any wavelength selected from the wavelength range of 2λ to 10λ in the longitudinal direction, wherein λ (μm) represents the shortest recording wavelength of a recording and reproducing device for the magnetic recording medium.

The present invention also relates to a method comprising the steps of:

subjecting the shape of irregularities of the surface of the magnetic layer to Fourier transformation, thereby obtaining the power spectrum density (PSD) in the width direction of the magnetic recording medium; and

judging the quality of the surface of the magnetic recording medium on the basis of the power spectrum density at any wavelength selected from the wavelength range of 2λ to 10λ in the width direction, wherein λ (μm) represents the shortest recording wavelength of a recording and reproducing device for the magnetic recording medium.

The power spectrum densities (PSDs) in the longitudinal direction and the width direction of the magnetic layer surface can be obtained by the method as described above. That is, the power spectrum densities can be obtained by dividing a measuring area of 93.9 μm (in the longitudinal direction)×123.5 μm (in the width direction) of the magnetic layer surface into 480 pixels (in the longitudinal direction)×736 pixels (in the width direction), so as to make the area of each of the pixels into 0.20 μm (in the longitudinal direction)×0.17 μm (in the width direction); measuring the shape of minute irregularities of the measuring area in the magnetic layer surface; and then subjecting the resultant heights of the irregularities to Fourier transformation.

At this time, the power spectrum density in the longitudinal direction and/or the power spectrum density in the width direction is evaluated at a short wavelength close the wavelength λ μm, e.g., in the wavelength range of 2λ to 10λ, wherein λ (μm) represents the shortest recording wavelength of the recording and reproducing device for the magnetic recording medium, whereby the degree of the irregularities of the magnetic layer surface can be evaluated in light of the recording wavelength made short.

For example, a recording medium wherein its power spectrum density L₂ at the wavelength 2λ in the longitudinal direction is6.0×10⁻⁶nm²mm or less can be judged as a good medium. According to a stricter standard, for example, a recording medium wherein its power spectrum density L₂ at the wavelength 2λ in the longitudinal direction is from 1.0×10⁻⁶ to 5.0×10⁻⁶ nm²mm (both inclusive) can be judged as a good medium.

For example, a recording medium wherein its power spectrum density W₂ at the wavelength 2λ in the width direction is 3.5×10⁻⁶ nm²mm or less can be judged as a good medium. According to a stricter standard, for example, a recording medium wherein its power spectrum density W₂ at the wavelength 2λ in the width direction is from 3.0×10⁻⁷ to 2.5×10⁻⁶ nm²mm (both inclusive) can be judged as a good medium.

### EXAMPLES

The present invention will be more specifically described byway of the following examples. However, the present invention is not limited to only these examples.

### Example 1

(Preparation of Magnetic Layer Coating Material)

| | |
|---|---|
| Ferromagnetic powder: | |
| Fe-based acicular magnetic powder (Fe/Co/Al/Y | 100.0 parts by weight |
| = 100/25/10/10 (atomic ratio)) | |
| (Hc: 179 kA/m (2250 Oe), σs: 140 Am²/kg | |
| (emu/g), average long axis length: 60 nm) | |
| Resins: | |
| vinyl chloride type resin | 12 parts by weight |
| (vinyl chloride copolymer, trade name: MR110, | |
| manufactured by Nippon Zeon Corp.) | |
| polyester polyurethane resin | 5 parts by weight |
| (polyester polyurethane, trade name: UR8700, | |
| manufactured by Toyobo Co., Ltd.) | |
| Abrasive: | |
| α- alumina | 10 parts by weight |
| (trade name: HIT60A, manufactured by | |
| Sumitomo Chemical Co., Ltd., average particle | |
| size: 0.18 μm) | |
| Dispersant: | |
| phosphoric acid ester | 1 parts by weight |
| (trade name: RE610, manufactured by TOHO | |
| Chemical Industry Co., Ltd.) | |
| Solid concentration = 30% by weight | |
| Solvent: methyl ethyl ketone (MEK) /toluene/ | |
| cyclohexanone = 4/4/2 (ratio by weight) | |

The above-mentioned materials from which a part of the organic solvent was removed were sufficiently subjected to kneading treatment with a kneader in a high-viscosity state. Next, the rest of the organic solvent was added to the kneaded materials, and then the mixture was sufficiently stirred in a dissolver. Thereafter, a disperser (a lateral type pin mill), filled with zirconia beads having an average particle size of 0.8 mm as dispersing media at a filling volume ratio of 75%, was used to conduct preparatory dispersing treatment at a dispersing peripheral velocity of 7 m/s while the mixture was circulated and supplied into the disperser at a residence time of 30 minutes.

Thereafter, the resultant mixed solution was diluted with an added solvent so as to have a solid concentration of 12% by weight and the following solvent ratio by weight: MEK/toluene/cyclohexanone=2/2/6. Thereafter, regular dispersion was performed at a dispersing peripheral velocity of 7 m/s in a disperser (trade name: GMH, manufactured by Asada Iron Works Co., Ltd., vessel volume: 4 liters), filled with zirconia beads having an average particle size of 0.7 mm at a filling volume ratio of 80%, while the mixed solution was circulated and supplied into the disperser at a residence time of 30 minutes.

To the prepared magnetic layer coating material were added 3 parts by weight of a curing agent (trade name: COLONATE L, manufactured by Nippon Polyurethane Industry Co., Ltd.), and then they were mixed. The resultant was sufficiently stirred in a dissolver and subsequently filtrated through a filter having an absolute filtration precision of 0.5 μm, so as to prepare a target magnetic layer coating material.

(Preparation of Non-Magnetic Layer Coating Material)

| | |
|---|---|
| Non-magnetic powder: | |
| acicular α-FeO₃ | 85 parts by weight |
| (BET specific surface area: 57 m²/g, pH: 5.7, | |
| average long axis length: 110 nm) | |
| Carbon black: | 15 parts by weight |
| (trade name: #950B, manufactured by Mitsubishi | |
| Chemical Co., Ltd., BET specific surface area: | |
| 260 m²/g, DBP oil absorption: 74 mL/100 g, pH: | |
| 8, average particle size: 16 nm) | |
| Resins: | |
| electron beam (EB) curable vinyl chloride | 12 parts by weight |
| copolymer | |
| (manufactured by Toyobo Co., Ltd., | |
| polymerization degree: 300, Tg: 70° C.) | |
| electron beam (EB) curable polyester | 10 parts by weight |
| polyurethane resin | |
| (manufactured by Toyobo Co., Ltd., number- | |
| average molecular weight: 25000, Tg: 10° C.) | |
| Abrasive: | |
| α-alumina | 5 parts by weight |
| (trade name: HIT60A, manufactured by | |
| Sumitomo Chemical Co., Ltd., average particle | |
| size: 0.18 pm) | |
| Dispersant: | |
| phosphoric acid ester | 1 parts by weight |
| (trade name: RE610, manufactured by TOHO | |
| Chemical Industry Co., Ltd.) | |
| Solid concentration = 30% by weight | |
| Solvent: methyl ethyl ketone (MEK)/toluene/ | |
| cyclohexanone = 4/4/2 (ratio by weight) | |

The above-mentioned materials from which a part of the organic solvent was removed were sufficiently subjected to kneading treatment with a kneader in a high-viscosity state. Next, the rest of the organic solvent was added to the kneaded materials, and then the mixture was sufficiently stirred in a dissolver. Thereafter, a disperser (a lateral type pin mill), filled with zirconia beads having an average particle size of 0.8 mm as dispersing media at a filling volume ratio of 80%, was used to conduct preparatory dispersing treatment while the mixture was circulated and supplied into the disperser at a residence time of 60 minutes.

Thereafter, the resultant mixed solution were added the following lubricants:

stearic acid: 0.5 part by weight, myristic acid: 0.5 part by weigh, and butyl stearate: 0.5 part by weigh.

These components were mixed, and then regular dispersion was performed at a dispersing peripheral velocity of 7 m/s in a disperser (trade name: GMH, manufactured by Asada Iron Works Co., Ltd., vessel volume: 4 liters), filled with zirconia beads having an average particle size of 0.8 mm at a filling volume ratio of 80%, while the mixed solution was circulated and supplied into the disperser at a residence time of 10 minutes.

The prepared non-magnetic layer coating material was filtrated through a filter having an absolute filtration precision of 0.5 μm, so as to prepare a target non-magnetic layer coating material.

(Preparation of Back Coat Layer Coating Material)

| | |
|---|---|
| Carbon black: | 75 parts by weight |
| (trade name: BP-800, manufactured by Cabot | |
| Corp., BET specific surface area: 210 m²/g, | |
| average particle size: 17 nm, DBP oil absorption: | |
| 68 mL/100 g) | |
| Carbon black | 15 parts by weight |
| (tradename: BP-130, manufactured by Cabot | |
| Corp., BET specific surface area: 25 m²/g, | |
| average particle size: 75 nm, DBP oil absorption: | |
| 69 mL/100 g,) | |
| Calcium carbonate: | 15 parts by weight |
| (trade name: HAKUENKA O, manufactured by | |
| Shiraishi Kogyo, average particle size: 30 nm) | |
| Nitrocellulose: | 65 parts by weight |
| (trade name: BTH1/2, manufactured by Asahi | |
| Kasei Corp.) | |
| Polyurethane resin: | 35 parts by weight |
| (aliphatic polyester diol/aromatic polyester diol | |
| = 43/57) | |
| Solid concentration = 30% by weight | |
| Solvent: MEK/toluene/cyclohexanone = | |
| 1/1/1 (ratio by weight) | |

The above-mentioned materials from which a part of the organic solvent was removed were sufficiently subjected to kneading treatment with a kneader in a high-viscosity state. Next, the rest of the organic solvent was added to the kneaded materials, and then the mixture was sufficiently stirred in a dissolver. Thereafter, a disperser (a lateral type pin mill), filled with zirconia beads having an average particle size of 0.8 mm as dispersing media at a filling volume ratio of 80%, was used to conduct preparatory dispersing treatment at a dispersing peripheral velocity of 7 m/s while the mixture was circulated and supplied into the disperser at a residence time of 60 minutes.

Thereafter, the resultant mixed solution was diluted with an added solvent so as to have a solid concentration of 10% by weight and the following solvent ratio by weight: MEK/toluene/cyclohexanone=5/4/1. Thereafter, regular dispersion was performed at a dispersing peripheral velocity of 7 m/s in a disperser (trade name: GMH, manufactured by Asada Iron Works Co., Ltd., vessel volume: 4 liters), filled with zirconia beads having an average particle size of 0.8 mm at a filling volume ratio of 80%, while the mixed solution was circulated and supplied into the disperser at a residence time of 10 minutes.

To the prepared magnetic layer coating material were added 5 parts by weight of a curing agent (trade name: COLONATE L, manufactured by Nippon Polyurethane Industry Co., Ltd.), and then they were mixed. The resultant was sufficiently stirred in a dissolver and subsequently filtrated through a filter having an absolute filtration precision of 0.5 μm, so as to prepare a target back coat layer coating material.

The non-magnetic layer coating material, magnetic layer coating material and back coat layer coating material obtained as described above were used to produce a sample of a magnetic recording medium as follows.

(Step of Applying Non-Magnetic Layer Coating Material)

The non-magnetic layer coating material was applied from a nozzle onto one surface of a polyethylene terephthalate support of 6.2 μm thickness, so as to make the thickness of the applied coating material after the following calendering into 2.0 μm. The coating material was dried, and subsequently the resultant layer was calendered with combinations of a plastic roll with a metal roll under the following conditions: the nip number: 4, working temperature: 100° C., linear pressure: 3500 N/cm, and velocity: 100 m/s. Furthermore, the resultant was irradiated with electron rays at 4.5 Mrad.

(Step of Applying Magnetic Layer Coating Material)

The magnetic layer coating material was applied from a nozzle onto the non-magnetic layer formed as described above so as to make the thickness of the applied coating material after the following calendering into 0.1 μm. The coating material was oriented and dried, and subsequently the resultant layer was calendered with combinations of a plastic roll with a metal roll under the following conditions: the nip number: 4, working temperature: 100° C., linear pressure: 3500 N/cm, and velocity: 100 m/s.

(Step of Applying Back Coat Layer Coating Material)

The back coat layer coating material was applied from a nozzle onto the other surface of the support so as to make the thickness of the applied coating material dried after the following drying into 0.6 μm. The coating material was dried, and subsequently the resultant layer was calendered with combinations of a plastic roll with a metal roll under the following conditions: the nip number: 4, working temperature: 100° C., linear pressure: 3500 N/cm, and velocity: 100 m/s.

The magnetic recording medium web obtained as described above was cured in an oven of 60° C. temperature for 24 hours, and then slit into a width of ½ inch to produce a magnetic recording tape sample.

### Examples 2 to 4, and Comparative Example 1

Magnetic recording tape samples were produced in the same way as in Example 1 except that each of the average long axis length (nm) of the ferromagnetic powder and the average particle size (mm) of the beads as the dispersing media used in the regular dispersion of the magnetic layer coating material was changed to be shown in Table 1.

Evaluating Method

(Method for Obtaining PSDs of Shapes of Irregularities in Longitudinal and Width Directions of Each Magnetic Layer Surface)

The curve forming the surface roughness of the magnetic layer surface of each of the magnetic recording media, and the intensity thereof were obtained by use of a system, Wyko NT-2000 System manufactured by Nihon Veeco K. K. in accordance with the following manner.

A Super Reference Mirror was placed on an XY 750 sample stage, and four points of the surface thereof were each measured by use of the following: a Mirau interference type 50-power lens having a numerical aperture (NA) of 0.55, a working distance of 3.4 mm, an optical resolving power of 0.55, and a maximum inclination angle of 25.0 degrees as an infinitely conjugated magnifying objective lens; a 1.0-power lens as an inner lens; software, Wyko Vision 32; and a phase shift interferometry (PSI) measuring manner. About each of the four points, the measurement was made four times to obtain the average of the measured values. All of the data were subjected to averaging-treatment to take out a shape of a reference surface peculiar to the objective lens. In this way, a reference surface was formed.

Next, the given magnetic recording medium slit into the ½ inch width, on which servo signals were recorded, was placed on the XY 750 sample stage so as to direct the magnetic layer toward the objective lens, and then generated interference fringes were adjusted to a null state in an XY direction inclination adjusting unit. About a measuring field of 93.9 μm (in the longitudinal direction)=123.5 μm (in the width direction) of the magnetic recording medium, light was projected through an interference system into a CCD camera having 480×736 pixels so as to make analysis four times. The average data of the resultant data were obtained. That is, each of the pixels was made of an area of 0.20 μm (in the longitudinal direction)×0.17 μm (in the width direction). Next, the resultant image data were subjected to inclination correction and cylindrical correction to remove the inclination and cylinder shape from the measurement data. Next, the corrected image data were subjected to Fourier transformation to obtain the frequency (1/mm) of the curve forming the shape of the irregularities in the longitudinal direction of the magnetic layer surface of the magnetic recording medium and the power spectrum density (PSD) (nm²mm) representing the frequency intensity thereof, and the frequency (1/mm) of the curve forming the shape of the irregularities in the width direction of the magnetic layer surface of the magnetic recording medium and the power spectrum density (PSD) (nm²mm) representing the frequency intensity thereof. Next, the obtained frequencies were converted to wavelengths (μm) so as to yield the target wavelengths (μm) of the curves forming the shapes of the irregularities in the longitudinal and width directions of the magnetic layer surface, and the wavelength intensities PSD (nm²mm) thereof.

(Measuring Method of Missing Pulse Ratio)

A magnetic recording head and a reproducing head were fitted to a Small Format Tape Evaluation System (hereinafter abbreviated to the SFTES) manufactured by Measurement Analysis Corp., and each of the magnetic tapes was traveled on the system. As the reproducing head, a magneto-resistive effect type head (MR head) was used.

The tape integrated into a cartridge was subjected to recording with a single recording wavelength of 0.25 μm. A P-0 signal of not more than 25% of the P-P value of a signal positioned a tape length of 2.54 cm ahead was defined as a missing pulse. Four or more continuous missing pulses were defined as long defects. The number of long defects per meter about a standard tape was represented by N0, and the number thereof about a comparative sample of the magnetic recording tape was represented by X. The two tapes were compared with each other by way of log₁₀(X/N0).

The results obtained as above are shown in Table 1 to 6. In the end of each of the tables, a correlation coefficient between the PSD (nm²mm) and the missing pulse ratio is shown.

Each of the tape samples of Examples 1 to 4 satisfying the requirements of the present invention exhibited an excellent missing pulse ratio, and were excellent in medium performance.

From Tables 1 and 2, about the wavelength (nm) twice the shortest recording wavelength of the recording and reproducing device and the wavelength (nm) 10 times the same wavelength, the PSD (nm²mm) in the longitudinal direction and the missing pulse ratio had good correlations (0.9748 and 0.8918), respectively. In other words, it can be concluded that the quality of the surface of a magnetic recording medium can be judged on the basis of the PSD at any wavelength selected from the wavelength range of 2λ to 10λ in the longitudinal direction, wherein λ (μm) represents the shortest recording wavelength of a recording and reproducing device.

From Tables 4 and 5, about the wavelength (nm) twice the shortest recording wavelength of the recording and reproducing device, and the wavelength (nm) 10 times the same wavelength, the PSD (nm²mm) in the width direction and the missing pulse ratio had good correlations (0.9538 and 0.8755), respectively. In other words, it can be concluded that the quality of the surface of a magnetic recording medium can be judged on the basis of the PSD at any wavelength selected from the wavelength range of 2λ to 10λ in the width direction, wherein λ (μm) represents the shortest recording wavelength of a recording and reproducing device.

TABLE 1
Longitudinal direction
Wavelength twice the shortest recording wavelength (0.25 μm)

| | Average | | | | |
|---|---|---|---|---|---|
| | long axis | Average | | | |
| | length of | particle | | | |
| | ferro- | size of | Shape of irregularities | | |
| | magnetic | dispersing | of tape surface | | Missing |
| | powder | beads | Wavelength | PSD | pulse |
| Sample | (nm) | (nm) | (μm) | (nm²mm) | ratio |
| Comparat- | 100 | 0.8 | 0.5 | 8.0 × 10⁻⁶ | 0 |
| tive | | | | | |
| Example 1 | | | | | |
| Example 1 | 60 | 0.7 | 0.5 | 6.0 × 10⁻⁶ | −0.39 |
| Example 2 | 60 | 0.5 | 0.5 | 5.0 × 10⁻⁶ | −0.66 |
| Example 3 | 45 | 0.3 | 0.5 | 4.0 × 10⁻⁶ | −0.96 |
| Example 4 | 45 | 0.1 | 0.5 | 3.0 × 10⁻⁶ | −1.37 |
| | | | | Correlation | 0.9748 |
| | | | | coefficient | |

TABLE 2
Longitudinal direction
Wavelength 10 times the shortest recording wavelength (0.25 μm)

| | Average | | | | |
|---|---|---|---|---|---|
| | long axis | Average | | | |
| | length of | particle | | | |
| | ferro- | size of | Shape of irregularities | | |
| | magnetic | dispersing | of tape surface | | Missing |
| | powder | beads | Wavelength | PSD | pulse |
| Sample | (nm) | (nm) | (μm) | (nm²mm) | ratio |
| Comparat- | 100 | 0.8 | 2.5 | 4.5 × 10⁻³ | 0 |
| tive | | | | | |
| Example 1 | | | | | |
| Example 1 | 60 | 0.7 | 2.5 | 3.5 × 10⁻³ | −0.39 |
| Example 2 | 60 | 0.5 | 2.5 | 3.4 × 10⁻³ | −0.66 |
| Example 3 | 45 | 0.3 | 2.5 | 3.0 × 10⁻³ | −0.96 |
| Example 4 | 45 | 0.1 | 2.5 | 1.0 × 10⁻³ | −1.37 |
| | | | | Correlation | 0.8918 |
| | | | | coefficient | |

TABLE 3
Longitudinal direction
Wavelength 20 times the shortest recording wavelength (0.25 μm)

| | Average | | | | |
|---|---|---|---|---|---|
| | long axis | Average | | | |
| | length of | particle | | | |
| | ferro- | size of | Shape of irregularities | | |
| | magnetic | dispersing | of tape surface | | Missing |
| | powder | beads | Wavelength | PSD | pulse |
| Sample | (nm) | (nm) | (μm) | (nm²mm) | ratio |
| Comparat- | 100 | 0.8 | 5.0 | 1.1 × 10⁻² | 0 |
| tive | | | | | |
| Example 1 | | | | | |
| Example 1 | 60 | 0.7 | 5.0 | 8.8 × 10⁻³ | −0.39 |
| Example 2 | 60 | 0.5 | 5.0 | 8.2 × 10⁻³ | −0.66 |
| Example 3 | 45 | 0.3 | 5.0 | 9.6 × 10⁻³ | −0.96 |
| Example 4 | 45 | 0.1 | 5.0 | 1.0 × 10⁻² | −1.37 |
| | | | | Correlation | 0.0338 |
| | | | | coefficient | |

TABLE 4
Width direction
Wavelength twice the shortest recording wavelength (0.25 μm)

| | Average | | | | |
|---|---|---|---|---|---|
| | long axis | Average | | | |
| | length of | particle | | | |
| | ferro- | size of | Shape of irregularities | | |
| | magnetic | dispersing | of tape surface | | Missing |
| | powder | beads | Wavelength | PSD | pulse |
| Sample | (nm) | (nm) | (μm) | (nm²mm) | ratio |
| Comparat- | 100 | 0.8 | 0.5 | 6.0 × 10⁻⁶ | 0 |
| tive | | | | | |
| Example 1 | | | | | |
| Example 1 | 60 | 0.7 | 0.5 | 3.5 × 10⁻⁶ | −0.39 |
| Example 2 | 60 | 0.5 | 0.5 | 2.5 × 10⁻⁶ | −0.66 |
| Example 3 | 45 | 0.3 | 0.5 | 1.5 × 10⁻⁶ | −0.96 |
| Example 4 | 45 | 0.1 | 0.5 | 5.0 × 10⁻⁷ | −1.37 |
| | | | | Correlation | 0.9538 |
| | | | | coefficient | |

TABLE 5
Width direction
Wavelength 10 times the shortest recording wavelength (0.25 μm)

| | Average | | | | |
|---|---|---|---|---|---|
| | long axis | Average | | | |
| | length of | particle | | | |
| | ferro- | size of | Shape of irregularities | | |
| | magnetic | dispersing | of tape surface | | Missing |
| | powder | beads | Wavelength | PSD | pulse |
| Sample | (nm) | (nm) | (μm) | (nm²mm) | ratio |
| Comparat- | 100 | 0.8 | 2.5 | 2.0 × 10⁻³ | 0 |
| tive | | | | | |
| Example 1 | | | | | |
| Example 1 | 60 | 0.7 | 2.5 | 1.5 × 10⁻³ | −0.39 |
| Example 2 | 60 | 0.5 | 2.5 | 1.3 × 10⁻³ | −0.66 |
| Example 3 | 45 | 0.3 | 2.5 | 1.4 × 10⁻³ | −0.96 |
| Example 4 | 45 | 0.1 | 2.5 | 6.0 × 10⁻⁴ | −1.37 |
| | | | | Correlation | 0.8755 |
| | | | | coefficient | |

TABLE 6
Width direction
Wavelength 20 times the shortest recording wavelength (0.25 μm)

| | Average | | | | |
|---|---|---|---|---|---|
| | long axis | Average | | | |
| | length of | particle | | | |
| | ferro- | size of | Shape of irregularities | | |
| | magnetic | dispersing | of tape surface | | Missing |
| | powder | beads | Wavelength | PSD | pulse |
| Sample | (nm) | (nm) | (μm) | (nm²mm) | ratio |
| Comparat- | 100 | 0.8 | 5.0 | 5.5 × 10⁻³ | 0 |
| tive | | | | | |
| Example 1 | | | | | |
| Example 1 | 60 | 0.7 | 5.0 | 4.8 × 10⁻³ | −0.39 |
| Example 2 | 60 | 0.5 | 5.0 | 4.7 × 10⁻³ | −0.66 |
| Example 3 | 45 | 0.3 | 5.0 | 7.0 × 10⁻³ | −0.96 |
| Example 4 | 45 | 0.1 | 5.0 | 2.0 × 10⁻³ | −1.37 |
| | | | | Correlation | 0.2207 |
| | | | | coefficient | |

What is claimed is:

1. A magnetic recording medium comprising:
a non-magnetic support;
a non-magnetic layer which is formed on one surface of the non-magnetic support and comprises at least carbon black, a non-magnetic powder other than the carbon black and a binder resin; and
a magnetic layer which is formed on the non-magnetic layer and comprises at least a ferromagnetic powder and a binder resin, wherein
when the shape of irregularities of the surface of the magnetic layer is subjected to Fourier transformation to obtain the power spectrum density (PSD) in the longitudinal direction of the magnetic recording medium, the power spectrum density L₂ at a wavelength 2λ in the longitudinal direction, wherein λ (μm) represents the shortest recording wavelength of a recording and reproducing device for the magnetic recording medium, is 6.0×10⁻⁶ nm²mm or less.

2. The magnetic recording medium according to claim 1, wherein the average long axis length of the ferromagnetic powder is 60 nm or less.

3. The magnetic recording medium according to claim 1, wherein the magnetic layer has a thickness of 100 nm or less.

4. The magnetic recording medium according to claim 1, wherein a recorded signal is reproduced by use of a magneto-resistive effect type head (MR head).

5. A magnetic recording medium comprising:
a non-magnetic support;
a non-magnetic layer which is formed on one surface of the non-magnetic support and comprises at least carbon black, a non-magnetic powder other than the carbon black and a binder resin; and
a magnetic layer which is formed on the non-magnetic layer and comprises at least a ferromagnetic powder and a binder resin, wherein
when the shape of irregularities of the surface of the magnetic layer is subjected to Fourier transformation to obtain the power spectrum density (PSD) in the width direction of the magnetic recording medium, the power spectrum density W₂ at a wavelength 2λ in the width direction, wherein λ (μm) represents the shortest recording wavelength of a recording and reproducing device for the magnetic recording medium, is 3.5×10⁻⁶ nm²mm or less.

6. The magnetic recording medium according to claim 5, wherein the average long axis length of the ferromagnetic powder is 60 nm or less.

7. The magnetic recording medium according to claim 5, wherein the magnetic layer has a thickness of 100 nm or less.

8. The magnetic recording medium according to claim 5, wherein a recorded signal is reproduced by use of a magneto-resistive effect type head (MR head).

9. A method for evaluating a magnetic recording medium comprising at least a non-magnetic support and a magnetic layer on one surface of the support, the method comprising the steps of:
subjecting the shape of irregularities of the surface of the magnetic layer to Fourier transformation, thereby obtaining the power spectrum density (PSD) in the longitudinal direction of the magnetic recording medium; and
judging the quality of the surface of the magnetic recording medium on the basis of the power spectrum density at any wavelength selected from the wavelength range of 2λ to 10λ in the longitudinal direction, wherein λ (μm) represents the shortest recording wavelength of a recording and reproducing device for the magnetic recording medium.

10. The method for evaluating the magnetic recording medium according to claim 9, wherein the magnetic recording medium in which the power spectrum density L₂ at the wavelength 2λ in the longitudinal direction is 6.0×10⁻⁶ nm²mm or less is judged as a good medium.

11. A method for evaluating a magnetic recording medium comprising at least a non-magnetic support and a magnetic layer on one surface of the support, the method comprising the steps of:
subjecting the shape of irregularities of the surface of the magnetic layer to Fourier transformation, thereby obtaining the power spectrum density (PSD) in the width direction of the magnetic recording medium; and
judging the quality of the surface of the magnetic recording medium on the basis of the power spectrum density at any wavelength selected from the wavelength range of 2λ to 10λ in the width direction, wherein λ (μm) represents the shortest recording wavelength of a recording and reproducing device for the magnetic recording medium.

12. The method for evaluating the magnetic recording medium according to claim 11, wherein the magnetic recording medium in which the intensity W₂ of the power spectrum density at the wavelength 2λ in the width direction is 3.5×10⁻⁶ nm²mm or less is judged as a good medium.
